(19) United States
(12) Patent Application Publication
(10) Pub. No.: US 2025/0301894 A1
(43) Pub. Date: Sep. 25, 2025

(54) DISPLAY PANEL, MANUFACTURING METHOD THEREOF AND DISPLAY DEVICE

(71) Applicant: WUHAN TIANMA MICROELECTRONICS CO., LTD., Wuhan (CN)

(72) Inventor: Quanpeng YU, Wuhan (CN)

(73) Assignee: WUHAN TIANMA MICROELECTRONICS CO., LTD., Wuhan (CN)

(21) Appl. No.: 18/864,390

(22) PCT Filed: Sep. 7, 2022
(86) PCT No.: PCT/CN2022/117436

§ 371 Date: Nov. 8, 2024

(30) Foreign Application Priority Data
Jun. 30, 2022 (CN) 202210769592.8

(51) Int. Cl. H10K 59/80; H10K 59/12; H10K 59/121; H10K 59/65; H10K 59/88

(52) U.S. Cl. CPC H10K 59/8792; H10K 59/1201; H10K 59/121; H10K 59/65; H10K 59/88

(57) ABSTRACT

Provided is a display panel and a manufacturing method thereof, and a display device. A first area and a second area of the display panel are adjacent to each other, and the light transmittance of the second area is smaller than that of the first area. The array layer of the display panel is provided at a side of the substrate and includes a plurality of circuit elements, a plurality of light-emitting elements are provided at a side, away from the substrate, of the array layer, and the shielding layer is provided at a side, facing the substrate, of the light-emitting elements and includes a first shielding layer and a second shielding layer. The first shielding layer overlaps with the light-emitting elements in the first area. The second shielding layer overlaps with the circuit elements and/or or the light-emitting elements in the second area.

### CROSS-REFERENCE TO RELATED APPLICATIONS

The present application claims priority to Chinese Patent Application No. 202210769592.8, entitled “Display panel, manufacturing method thereof and display device”, filed on Jun. 30, 2022, the entire contents of which are incorporated herein by reference.

### TECHNICAL FIELD

The present disclosure relates to the field of display technologies, and in particular, to a display panel, a manufacturing method thereof, and a display device.

### BACKGROUND

With the continuous development of display technologies, full-screen has become a mainstream display screen design, which has an ultra-high screen-to-body ratio. In order to make the display screen have a higher screen-to-body ratio, the CUP (camera under panel) technology has been concerned by more and more manufacturers. In the CUP technology, the optical devices such as cameras provide on the back of the display area of the display screen, and the area where these cameras and optical sensors are arranged is referred to as the CUP area. It can be seen that the CUP area can not only display images, but also transmit light required by the camera. However, how to effectively achieve high light transmittance of the CUP area is an urgent problem to be solved.

### SUMMARY

In view of this, embodiments of the present disclosure provide a display panel, a manufacturing method thereof, and a display device.

In a first aspect, an embodiment of the present disclosure provides a display panel, a display area of the display panel includes a first area and a second area, the second area and the first area are adjacent to each other, and light transmittance of the second area is less than light transmittance of the first area.

The display panel includes:
a substrate;
an array layer provided at a side of the substrate, and including a plurality of circuit elements;
a plurality of light-emitting elements provided at a side of the array layer away from the substrate; and
shielding layers provided at a side of the light-emitting elements facing the substrate, and including a first shielding layer and a second shielding layer.

The first shielding layer overlaps with the light-emitting elements in the first area.

The second shielding layer overlaps with the circuit elements and/or the light-emitting elements in the second area.

In a second aspect, the present disclosure provides a display device including the display panel according to the first aspect.

In a third aspect, an embodiment of the present disclosure provides a manufacturing method of a display panel for preparing the display panel according to the first aspect.

In embodiments of the present disclosure, the light transmittance of the first area of is greater than the light transmittance of the second area in the display panel and the display device, and at least part of the film layer in the first area is etched off by laser to increase the light transmittance of the first area. In order to increase the etching rate of the film layer in the first area by the laser, the film layer in the first area may be laser etched by using a linear laser, and if the shape of the first area is of a non-rectangular structure, an etching path of the linear laser would inevitably exceed the first area. According to the present disclosure, the first shielding layer overlapping with the light-emitting element is provided in the first area, so that the film layer in the light-emitting element can be protected from being etched off by laser, and the second shielding layer is provided in the second area, so that the film layer in the second area can be protected from being misetched.

### BRIEF DESCRIPTION OF DRAWINGS

In order to more clearly describe the technical solutions of embodiments of the present disclosure, the following briefly describes the drawings desired in the embodiments. It is appreciated that the drawings described below are merely some embodiments of the present disclosure, and for those skilled in the art, other drawings can also be obtained based on these drawings without creative effort.

FIG. 1 is a schematic diagram of a display panel provided by an embodiment of the present disclosure;

FIG. 2 is a schematic diagram of a display panel provided by an embodiment of the present disclosure;

FIG. 3 is a partial schematic diagram of a CC area in a dashed box in FIG. 1 and FIG. 2;

FIG. 4 is a schematic cross-sectional view along a direction MM′ in FIG. 3;

FIG. 5 is a schematic cross-sectional view along a direction NN′in FIG. 3;

FIG. 6 is a partial schematic diagram of a CC area in a dashed box in FIG. 1 and FIG. 2;

FIG. 7 is a schematic cross-sectional view along a direction MM′ in FIG. 6;

FIG. 8 is a schematic cross-sectional view along a direction NN′in FIG. 6;

FIG. 9 is a partial cross-sectional view of a first area and a second area of a display panel provided by an embodiment of the present disclosure;

FIG. 10 is a partial cross-sectional view of a first area and a second area of a display panel provided by an embodiment of the present disclosure;

FIG. 11 is another partial schematic diagram of a CC area in a dashed box in FIG. 1 and FIG. 2;

FIG. 12 is another partial schematic diagram of a CC area in a dashed box in FIG. 1 and FIG. 2;

FIG. 13 is another schematic cross-sectional view along a direction MM′ in FIG. 3;

FIG. 14 is another schematic cross-sectional view along a direction NN′in FIG. 6;

FIG. 15 is another partial schematic diagram of a CC area in a dashed box in FIG. 1 and FIG. 2;

FIG. 16 is another schematic cross-sectional view along a direction MM′ in FIG. 3;

FIG. 17 is another schematic cross-sectional view along a direction MM′ in FIG. 3;

FIG. 18 is another partial schematic diagram of a CC area in a dashed box in FIG. 1 and FIG. 2;

FIG. 19 is a schematic diagram of channel width-to-length ratios of circuit elements in different sub-areas in the second area;

FIG. 20 is a schematic diagram of channel width-to-length ratios of circuit elements in different sub-areas in the second area;

FIG. 21 is a schematic diagram of channel width-to-length ratios of circuit elements in different sub-areas in the second area;

FIG. 22 is a schematic projection diagram of a second shielding layer provided by an embodiment of the present disclosure;

FIG. 23 is a schematic projection diagram of a second shielding layer provided by an embodiment of the present disclosure;

FIG. 24 is a schematic projection diagram of a second shielding layer provided by an embodiment of the present disclosure;

FIG. 25 is a schematic projection diagram of a second shielding layer provided by an embodiment of the present disclosure;

FIG. 26 is a schematic projection diagram of a second shielding layer provided by an embodiment of the present disclosure;

FIG. 27 is a schematic projection diagram of a second shielding layer provided by an embodiment of the present disclosure;

FIG. 28 is a schematic projection diagram of a second shielding layer provided by an embodiment of the present disclosure;

FIG. 29 is a schematic projection diagram of a second shielding layer provided by an embodiment of the present disclosure;

FIG. 30 is a schematic projection diagram of a second shielding layer provided by an embodiment of the present disclosure;

FIG. 31 is a schematic projection diagram of a second shielding layer provided by an embodiment of the present disclosure;

FIG. 32 is a schematic projection diagram of a second shielding layer provided by an embodiment of the present disclosure;

FIG. 33 is a schematic projection diagram of a second shielding layer provided by an embodiment of the present disclosure;

FIG. 34 is a schematic diagram of a display device provided by an embodiment of the present disclosure;

FIG. 35 is a schematic diagram of a manufacturing method of a display panel provided by an embodiment of the present disclosure;

FIG. 36 is a schematic diagram of a relationship between a linear laser and a second shielding layer in a display panel provided by an embodiment of the present disclosure; and

FIG. 37 is a schematic diagram of a relationship between a linear laser and a second shielding layer in a display panel provided by an embodiment of the present disclosure.

### DESCRIPTION OF EMBODIMENTS

In order to better understand technical solutions of the present disclosure, the embodiments of the present disclosure are described in details with reference to the drawings.

It should be appreciated that the described embodiments are merely some, rather than all, of the embodiments of the present disclosure. All other embodiments obtained by a person of ordinary skill in the art based on the embodiments of the present disclosure shall fall within the protection scope of the present disclosure.

Terms used in the embodiments of the present disclosure are only for the purpose of describing specific embodiments, and are not intended to limit the present disclosure. The terms “a”, “an”, “the” and “said” in a singular form in an embodiment of the present disclosure and the attached claims are also intended to include plural forms thereof, unless explicitly noted otherwise in the context.

It should be understood that the term “and/or” used herein is merely an association relationship describing an associated object, and indicates that there may be three relationships. For example, A and/or B may indicate three situations: A alone, both A and B, and B alone. In addition, the character “/” herein generally indicates an “or” relationship between the associated objects.

In the description of the present disclosure, it should be understood that the terms such as “substantially”, “approximate to”, “approximately”, “about”, “roughly”, and “in general” described in the claims and embodiments of the present disclosure mean general agreement within a reasonable process operation range or tolerance range, rather than an exact value.

It should be understood that although the terms such as first, second, and third may be used to describe areas in the embodiments of the present disclosure, these areas should not be limited by these terms. These terms are used only to distinguish the areas from one another. For example, without departing from the scope of the embodiments of the present disclosure, a first area may also be referred to as a second area, and similarly, a second area may also be referred to as a first area.

Through careful and in-depth research, the embodiments of the present disclosure provide a solution for the problems existing in the related art.

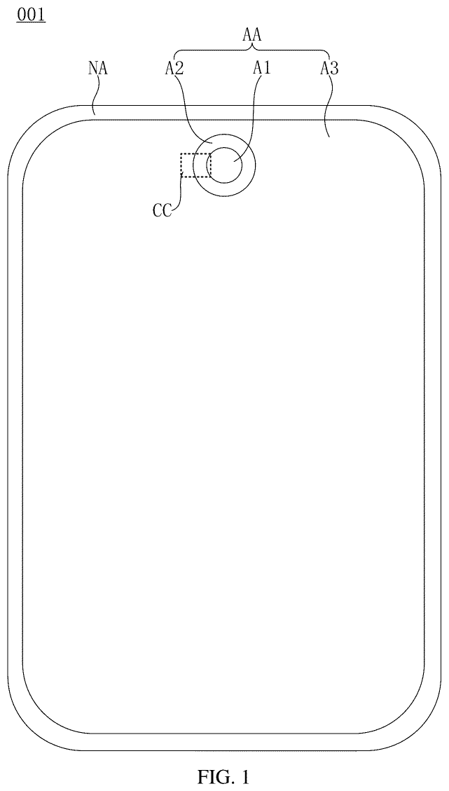

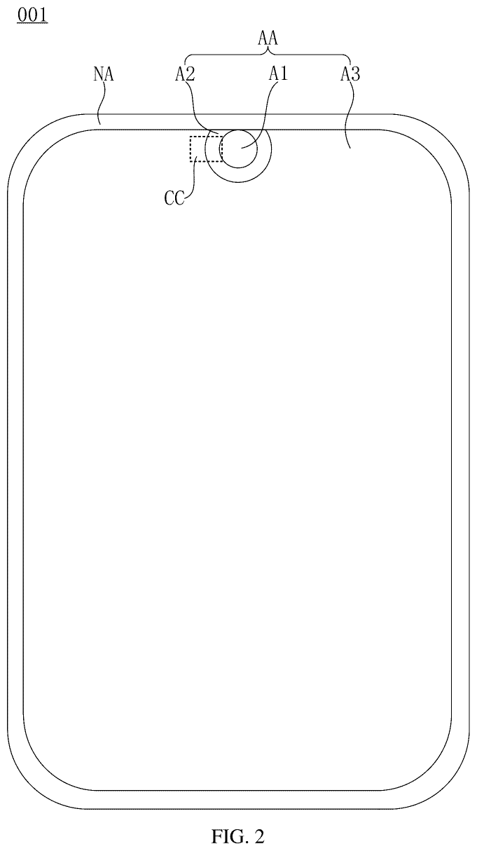

FIG. 1 is a schematic diagram of a display panel provided by an embodiment of the present disclosure. FIG. 2 is a schematic diagram of a display panel provided by an embodiment of the present disclosure.

An embodiment of the present disclosure provides a display panel, as shown in FIG. 1 and FIG. 2. The display panel 001 is divided into a display area AA and a non-display area NA, the non-display area NA surrounds the display area AA, the display area AA is the main region for light-emitting display, and the non-display area NA is mainly used for providing an encapsulation structure, a peripheral circuit, a peripheral signal line, and the like.

The display area AA includes a first area A1 and a second area A2, the second area A2 and the first area A1 may be adjacent to each other, and the light transmittance of the second area A2 is less than that of the first area A1. The first area A1 and the second area A2 are different areas in the display area AA, and the first area A1 has higher transmittance to external light than the second area A2. Further, the second area A2 may at least partially surround the first area A1.

The first area A1 has higher transmittance to external light, and the area where the first area A1 is located may be used to provide an optical functional element. For example, an element integrated with an optical sensor, such as a camera and a fingerprint identification structure may be provided below the first area A1. In addition to the function of light-emitting display, the first area A1 may further implement an optical signal transmission function, for example, at least one of the functions such as photographing and biometric recognition.

As shown in FIG. 1, the second area A2 may completely surround the first area A1. As shown in FIG. 2, the second area A2 may also partially surround the first area A1. Of course, the first area A1 may has a shape of such as a circle, an ellipse, or a rectangle.

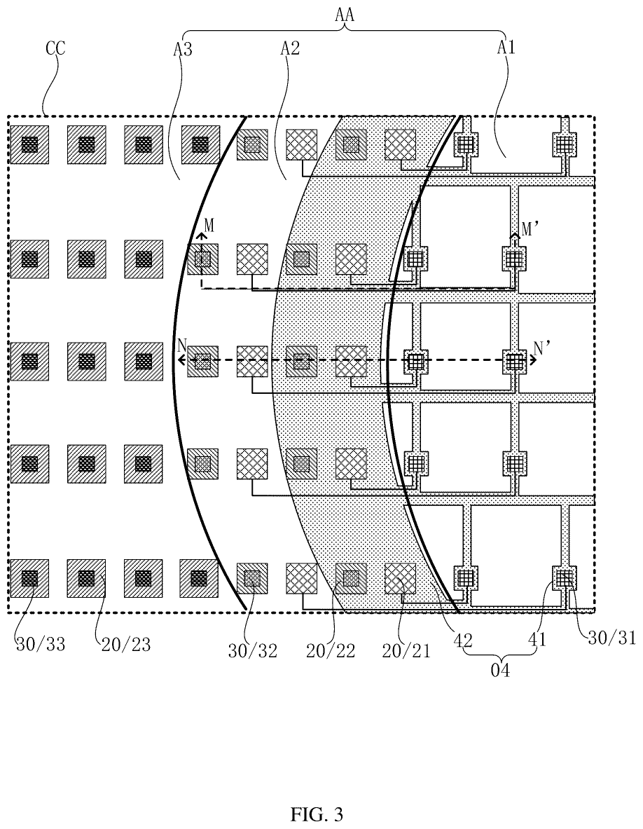

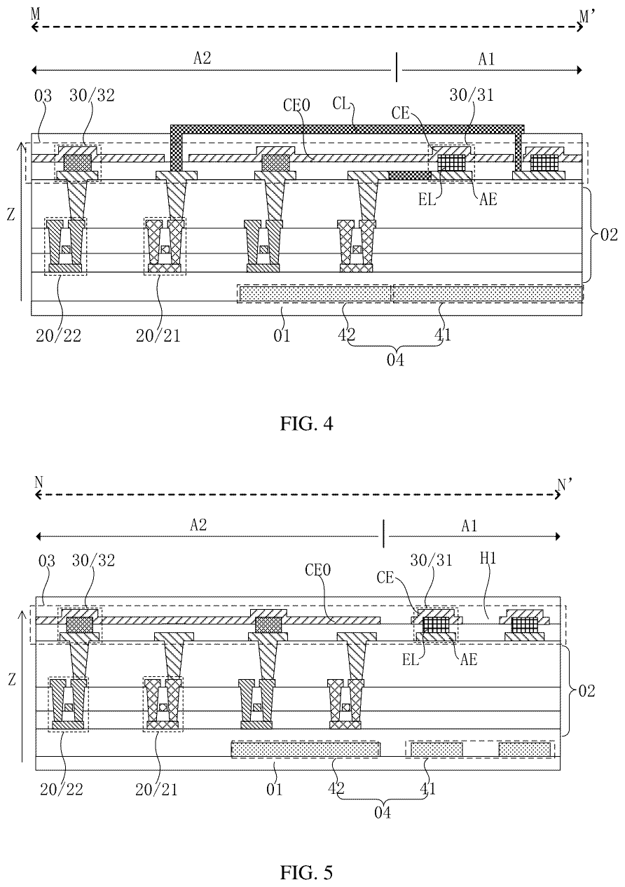

FIG. 3 is a partial schematic diagram of a CC area in a dashed box in FIG. 1 and FIG. 2. It should be understood that the dashed box area is merely used for clearly illustrating a CC area defined by a partial second area A2, and does not represent the actual area of the present disclosure. FIG. 4 is a schematic cross-sectional view along a direction MM′ in FIG. 3. FIG. 5 is a schematic cross-sectional view along a direction NN′ in FIG. 3.

With reference to FIG. 3, FIG. 4 and FIG. 5, the display panel 001 includes a substrate 01, an array layer 02, and a light-emitting element layer 03. The array layer 02 is provided at a side of the substrate 01 and includes a plurality of circuit elements 20, and the light-emitting element layer 03 is provided at a side of the array layer 02 away from the substrate 01 and includes a plurality of light-emitting elements 30.

The light-emitting elements 30 are the main structures for emitting light in the display panel 001, and may specifically be organic light-emitting diodes. The circuit elements 20 may specifically be transitors. A plurality of circuit elements 20 may constitute a pixel circuit that is connected to the light-emitting element 30 and provide the voltage and current required for its light-emitting. For example, when the light-emitting element 30 is an organic light-emitting diode, the plurality of circuit elements 20 may constitute a pixel circuit that provides the current required for the organic light-emitting diode light-emitting. Hereinafter, the inventive concept of the present disclosure is described with the circuit element 20 electrically connected to the light-emitting element 30 in the pixel circuit, and it can be understood that the design concept of the light-emitting element 30 in the present disclosure is also applicable to circuit elements with other functions in the pixel circuit.

In addition, the display panel further includes shielding layers 04 provided at a side of the light-emitting element layer 03 facing the substrate 01. The shielding layers 04 overlap with a part of the light emitting elements 30 to protect the light emitting elements 30 from the influence of the etching laser irradiating from the back of the display panel 001, thereby ensuring the integrity and the light-emitting performance of the light emitting elements 30.

In an embodiment of the present disclosure, the shielding layers 04 include a first shielding layer 41 and a second shielding layer 42, the first shielding layer 41 overlaps with the light-emitting elements 30 in the first area A1, and the second shielding layer 42 overlaps with the circuit elements 20 and/or the light-emitting elements 30 in the second area A2. That is, the shielding layers 04 include the first shielding layer 41 located in the first area A1 and the second shielding layer 42 located in the second area A2, and along the direction Z perpendicular to the display panel 001, the first shielding layer 41 in the first area A1 overlaps with the light-emitting elements 30 in the first area A1, and the second shielding layer 42 in the second area A2 overlaps with the light-emitting elements 30 in the second area A2.

As shown in FIGS. 3 to 5, the plurality of light-emitting elements 30 arranged in the light-emitting element layer 03 include first light-emitting elements 31 and second light-emitting elements 32, the first light-emitting element 31 is a light-emitting element 30 arranged in the first area A1, and the second light-emitting element 32 is a light-emitting element 30 arranged in the second area A2.

For example, as shown in FIGS. 3 to 5, the first shielding layer 41 in the first area A1 overlaps with the first light-emitting elements 31 in the first area A1, and the second shielding layer 42 in the second area A2 overlaps with the second light-emitting elements 32 in the second area A2. Meanwhile, the second shielding layer 42 in the second area A2 may also overlap with the circuit elements 20 in the second area A2.

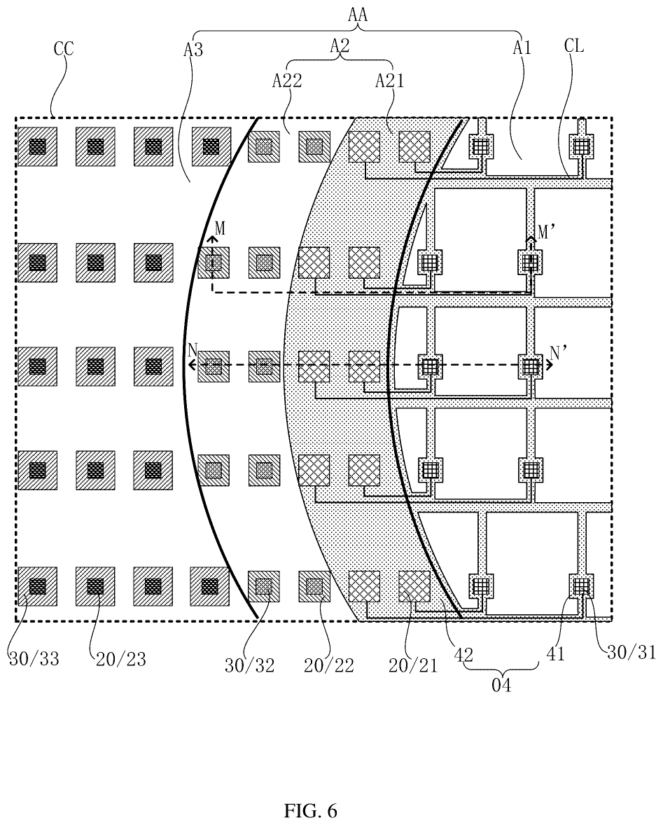

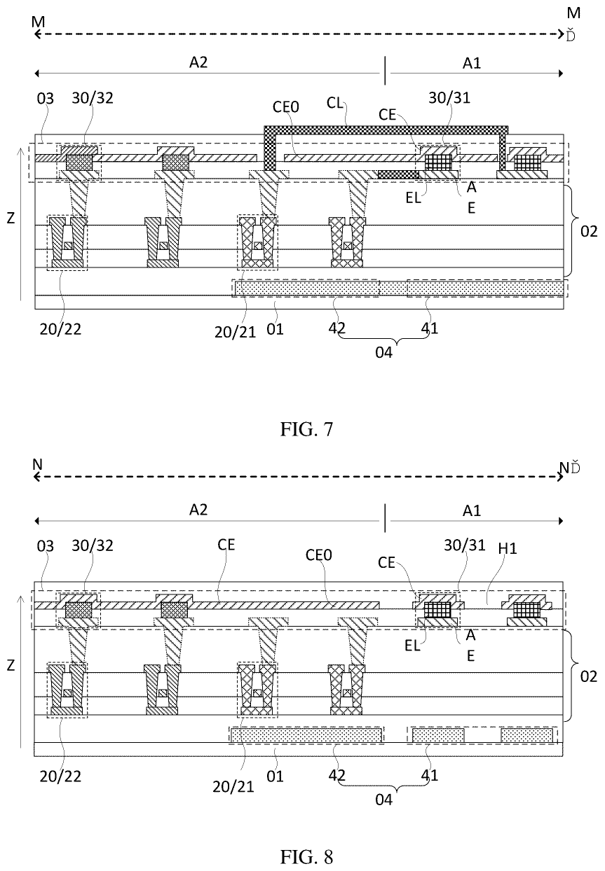

FIG. 6 is a partial schematic diagram of a CC area in a dashed box in FIG. 1 and FIG. 2. FIG. 7 is a schematic cross-sectional view along the direction MM′ in FIG. 6. FIG. 8 is a schematic cross-sectional view along the direction NN′ in FIG. 6.

For example, as shown in FIGS. 6 to 8, the first shielding layer 41 in the first area A1 overlaps with the first light-emitting elements 31 in the first area A1, and the second shielding layer 42 in the second area A2 overlaps with the circuit elements 20 in the second area A2 and does not overlap with the second light-emitting elements 32 in the second area A2.

It has been found through research that, in order to achieve high light transmittance of the first area A1, the black matrix in the first area A1 is generally designed as an opening, and the black matrix in the first area A1 only retains the part surrounding the color resist. The opening design of the black matrix in the first area A1 exposes a larger area of the cathode layer CE0. Since the cathode layer CE0 is made of a magnesium-silver material, the reflectivity of the first area A1 is increased, and the magnesium-silver material may, to some degree, shield light that need to enter optical functional elements such as a camera, so that the cathode layer CE0 exposed by the opening of the black matrix needs to be patterned by using a laser etching process.

Meanwhile, it have been found that, when the cathode layer CE0 is etched by using laser, misetching is caused to the cathode layer CE0 at the periphery of the first area A1. It have been found by analysis that the main reason for this problem is that, when the dot-shaped laser is used, the laser would overetch the film layer in the second area A2 when reaching the edge of the first area A1 due to the light spot of the laser being within 20 μm-30 μm; and when the linear laser is used to etch the film layer in the first area A1, if the shape of the first area A1 is a non-rectangular structure, the etching path of the linear laser would inevitably exceed the first area A1 and the film layer in the second area A2 would be overetched.

In an embodiment of the present disclosure, the light transmittance of the first area A1 is greater than the light transmittance of the second area A2, and at least part of the film layer in the first area A1 is etched off by laser to increase the light transmittance of the first area A1. A specific manner of etching the part of the film layer in the first area A1 by using the laser is that the laser source emits laser from the back of the display panel 001 to the film layer that needs to be partially etched, that is, the laser is emitted from the side, away from the light-emitting element layer 03, of the substrate 01 to the film layer that needs to be partially etched. Therefore, since the first area A1 is provided with the first shielding layer 41 overlapping with the light emitting elements 20, the film layer in the light emitting elements 20 in the first area A1 can be protected from being etched off by laser, and since the second area A2 is provided with the second shielding layer 42, the film layer in the second area A2 can be protected from being misetched.

In an embodiment of the present disclosure, the first shielding layer 41 may cover the first light-emitting elements 31, and the second shielding layer 42 may cover the second light-emitting elements 32.

In an embodiment of the present disclosure, as shown in FIGS. 3 to 8, the plurality of circuit elements 20 arranged in the array layer 02 include first circuit elements 21. The first circuit element 21 is electrically connected to the first light-emitting element 31. The first light-emitting elements 31 are arranged in the first area A1 and the first circuit elements 21 are arranged in the second area A2. That is, the first area A1 does not provide the first circuit elements 21 electrically connected to the first light-emitting elements 31 in the first area A1. Instead, the first circuit elements 21 are disposed in the second area A2 on the periphery of the first area A1, so that the transmittance of the first area A1 to external light can be increased.

As shown in FIGS. 3, 4, 6 and 7, the first light-emitting element 31 disposed in the first area A1 and the second light-emitting element 32 disposed in the second area A2 are electrically connected to each other through a connection electrode CL. The connection electrode CL may be made of a transparent conductive electrode.

In an implementation of this embodiment, the plurality of circuit elements 20 disposed in the array layer 02 include second circuit elements 22. The second circuit element 22 is electrically connected to the second light-emitting element 32. Both the second circuit elements 22 and the second light-emitting elements 32 are arranged in the second area A2. In other words, the second area A2 provides not only the second circuit elements 22 electrically connected to the second light-emitting elements 32 in the second area A2, but also the first circuit elements 21 electrically connected to the first light-emitting elements 31 in the first area A1.

In addition, as shown in FIGS. 1, 2, 3 and 6, the display panel 001 further includes a third area A3. The second area A2 is located between the first area A1 and the third area A3.

In an embodiment, the plurality of circuit elements 20 arranged in the array layer 02 include third circuit elements 23, and the plurality of light-emitting elements 30 arranged in the light-emitting element layer 03 include a plurality of third light-emitting elements 33. The third circuit element 23 is electrically connected to the third light-emitting element 33. The third circuit elements 23 and the third light-emitting elements 33 are both arranged in the third area A3. That is, the circuit elements 20 arranged in the third area A3 may be electrically connected only to the light-emitting elements 30 in the third area A3.

In the present embodiment, if an optical functional element is provided below the display panel 001, the optical functional element may be specifically provided below the first area A1, and the first area A1 may correspond to an optical functional element area of the display device. The third area A3 may be a conventional display area for conventional display (this area in the present embodiment is a necessary and unimportant area, which is not described herein again, and will be described in detail below). The second area A2 may be a transition area provided between the first area A1 and the third area A3.

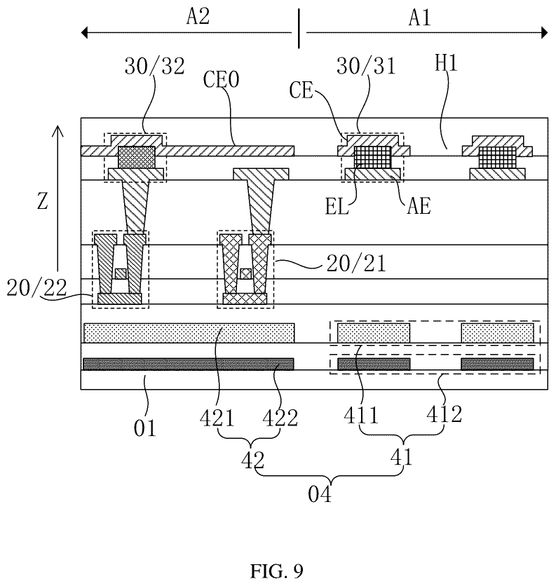

FIG. 9 is a partial cross-sectional view of a first area and a second area of a display panel provided by an embodiment of the present disclosure.

In an embodiment of the present disclosure, as shown in FIG. 9, each of the first shielding layer 41 and the second shielding layer 42 includes a plurality of sub-shielding layers stacked with one another, the number of the sub-shielding layers included in the first shielding layer 41 and the number of the sub-shielding layers included in the second shielding layer 42 are the same, and the sub-shielding layers included in the first shielding layer 41 and the second shielding layer 42 are arranged in the same layer, respectively. For example, as shown in FIG. 9, the first shielding layer 41 includes a sub-shielding layer 411 and a sub-shielding layer 412 that are stacked with one another, and the second shielding layer 42 includes a sub-shielding layer 421 and a sub-shielding layer 422 that are stacked with one another. The sub-shielding layer 411 and the sub-shielding layer 421 are arranged in a same layer, and the sub-shielding layer 412 and the sub-shielding layer 422 are arranged in a same layer.

It should be noted that an insulating layer may be arranged between the sub-shielding layers included in the first shielding layer 41 shown in FIG. 9, and an insulating layer may be arranged between the sub-shielding layers included in the second shielding layer 42. In an actual product, the plurality of sub-shielding layers included in the first shielding layer 41 may be stacked with one another and do not include an insulating layer therebetween. The plurality of sub-shielding layers included in the second shielding layer 42 may also be stacked with one another and do not include an insulating layer therebetween.

In addition, the first shielding layer 41 includes a shielding sub-layer of a metal material and a shielding sub-layer with higher absorbance, and the second shielding layer 42 includes a shielding sub-layer of a metal material and a shielding sub-layer with higher absorbance. The sub-shielding layer with higher absorbance may be a sub-shielding layer with absorbance greater than or equal to 50%, preferably a sub-shielding layer with absorbance greater than or equal to 65%.

For example, as shown in FIG. 9, materials of the sub-shielding layer 411 and the sub-shielding layer 421 are both metal Mo, and the sub-shielding layer 412 and the sub-shielding layer 422 are both made of Si in a gray-black color. The sub-shielding layer made of the metal material can reflect the laser more effectively, so as to prevent the laser from etching other structures in the display panel. The sub-shielding layer with higher absorbance can absorb part of the laser light directed towards the sub-shielding layer made of the metal material, thereby reducing the interference of the laser light reflected by the sub-shielding layer made of the metal material with the display light emitted by the light-emitting element 30. In addition, the sub-shielding layer with higher absorbance may be configured to cover the sub-shielding layer prepared from the metal material, and the area of the sub-shielding layer with higher absorbance is larger than that of the sub-shielding layer prepared from the metal material, so that light emitted by the light-emitting element 30 to a side of the substrate 01 can be absorbed by the sub-shielding layer with higher absorbance, thereby preventing this part of light from affecting the collection of external light signals by the optical functional element below the first area A1.

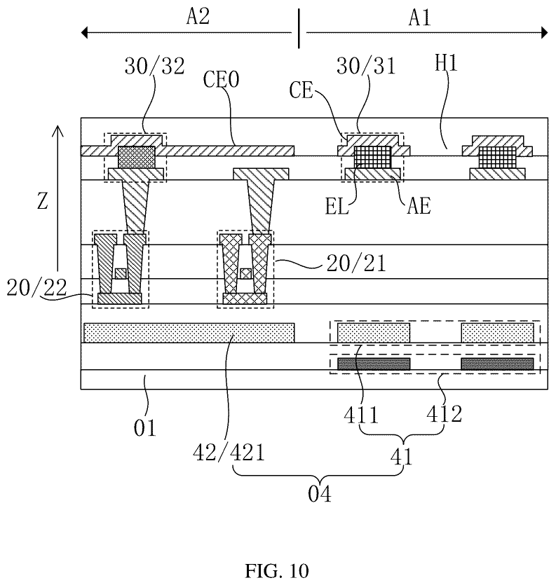

FIG. 10 is a partial cross-sectional view of a first area and a second area of a display panel provided by an embodiment of the present disclosure.

In an embodiment of the present disclosure, as shown in FIG. 10, the first shielding layer 41 arranged in the first area A1 includes n sub-shielding layers stacked with one another, and the second shielding layer 42 arranged in the second area A2 includes m sub-shielding layers stacked with one another, where n>m. For example, as shown in FIG. 10, the first shielding layer 41 arranged in the first area A1 includes two sub-shielding layers stacked in layers, namely, a sub-shielding layer 411 and a sub-shielding layer 412; and the second shielding layer 42 arranged in the second area A2 includes one sub-shielding layer 421, namely, a sub-shielding layer 411 and a sub-shielding layer 412, where n=2 and m=1.

By reducing the number of the sub-shielding layers included in the second shielding layer 42 in the second area A2, the influence of the second shielding layer 42 on the capacitive coupling of the second circuit elements 22 and the signal lines in the second area A2 can be reduced. Meanwhile, the first shielding layer 41 in the first area A1 includes at least two sub-shielding layers, so that the first shielding layer 41 can effectively reduce the influence of the reflected laser light on the display light emitted by the light emitting element 20, and can reduce the interference of the light emitting element 20 on the light signal required by the optical functional element arranged below the first area A1, as analyzed in the previous embodiment, when the display panel is displaying and the first area A1 needs to transmit external light at the same time.

In an embodiment, at least one sub-shielding layer in the first shielding layer 41 and at least one sub-shielding layer in the second shielding layer 42 are arranged in a same layer and made of a same material. In other words, the at least one sub-shielding layer in the first shielding layer 41 and the at least one sub-shielding layer in the second shielding layer 42 are manufactured by a same process, so that the number of use times of the mask during the manufacturing process can be reduced, thereby reducing process steps and reducing process costs.

The sub-shielding layer in the first shielding layer 41 and the sub-shielding layer in the second shielding layer 42 which are arranged in the same layer are both made of metal materials. For example, as shown in FIG. 10, the sub-shielding layer 411 in the first shielding layer 41 and the sub-shielding layer 421 in the second shielding layer 42 are both made of metal Mo. The sub-shielding layer made of the metal material can reflect the laser more effectively, so as to prevent the laser from etching other structures in the display panel.

In addition, the first shielding layer 41 may further include at least one sub-shielding layer with relatively high absorbance. For example, as shown in FIG. 10, relative to the second shielding layer 42, the first shielding layer 41 may further include a sub-shielding layer 412, and the sub-shielding layer 412 may be made of Si in a gray-black color. Therefore, as analyzed in the previous embodiment, the sub-shielding layer 412 can effectively reduce the influence of the reflected laser light on the display light emitted by the light-emitting element 20, and can reduce the interference of the light-emitting element 20 on the light signal required by the optical functional element arranged below the first area A1.

FIG. 11 is another partial schematic diagram of a CC area in a dashed box in FIG. 1 and FIG. 2.

In an embodiment of the present disclosure, as shown in FIGS. 4, 5, 7, and 8, each light-emitting element 30 includes a cathode CE, an anode AE, and a light-emitting material layer EL provided between the cathode CE and the anode AE. The value of the electric field between the cathode CE and the anode AE control the value of the brightness of the light emitted from the light-emitting material layer EL. In order to ensure that each light emitting element 30 can emit light with different brightness, the anode AE of each light emitting element 30 may be electrically connected to different circuit elements 20, and the cathodes CE of the light emitting elements 30 may be electrically connected to each other and all arranged in the cathode layer CE0.

Referring to FIG. 11 and FIG. 5, the cathode layer CE0 in which the cathodes CE of the light-emitting elements 30 are located includes a first hollow portion H1. In an embodiment, the first hollow portion H1 is provided in the first area A1. It can be understood that the light-emitting element 30 includes the cathode CE in the cathode layer CE0. Similarly, in the first area A1, the first light-emitting element 31 also includes the cathode CE. In the first area A1, the first light-emitting element 31 does not overlap with the first hollow portion H1.

In the present embodiment, referring to FIG. 11 and FIG. 5, the first shielding layer 41 in the first area A1 overlaps with the first light-emitting element 31 in the first area A1. In the first area A1, the first light-emitting element 31 does not overlap with the first hollow portion H1. That is, the first hollow portion H1 in the first area A1 does not overlap with the first shielding layer 41 in the first area, while the second shielding layer 42 in the second area A2 overlaps with the second light-emitting element 32 in the second area A2.

At least part of the cathode layer CE0 located in the first area A1 is configured as including the first hollow portion H1, so that the transmittance of the first area A1 to external light can be increased. In addition, the cathode CE is usually made of a magnesium-silver material. The magnesium-silver material has an obvious reflection effect on light and a poor transmission effect on light. As a result, the cathode layer CE0 in the first area A1 is configured as including the first hollow portion H1, so that the transmission effect of the first area A1 on light can be significantly improved and the reflection effect of the first area A1 on light can be reduced.

In addition, the light-emitting element 30 includes the cathode CE and the first shielding layer 41 overlaps with the first light-emitting element 31. As a result, the shielding layer 40 in the first area A1 overlaps with the light-emitting element 30 in the first area A1, and the first hollow portion H1 in the first area A1 does not overlap with the shielding layer 40 in the first area A1. In this case, the specific implementation manner of the first hollow portion H1 includes that the laser irradiated from the back of the display panel 001 to the cathode layer CE0 in the first area A1, so that the cathodes CE in the first area A1 which are shielded by the first shielding layer 41 would not be etched off by laser, while the part of the cathode layer CE0 in the first area A1 which is not shielded by the first shielding layer 41 will be etched by laser.

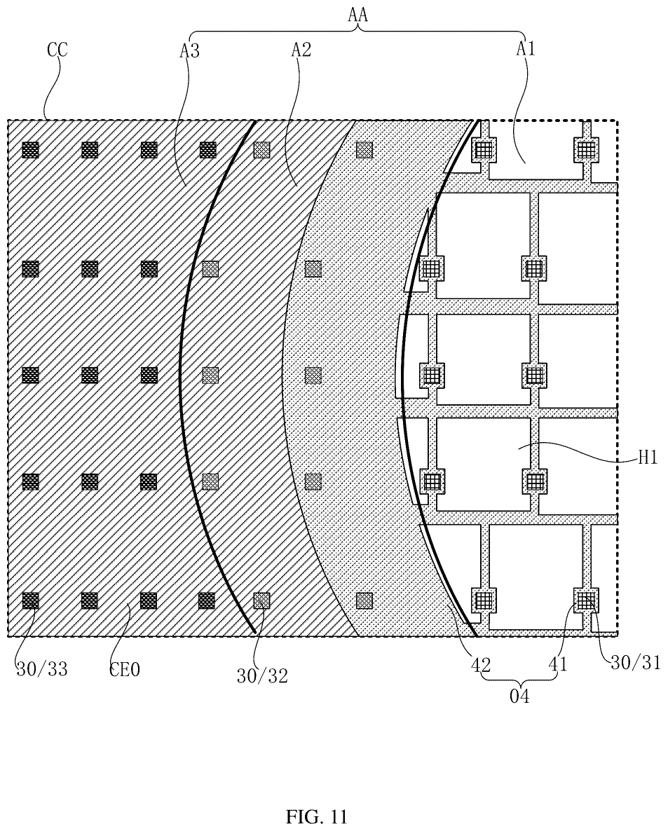

FIG. 12 is another partial schematic diagram of a CC area in a dashed box in FIG. 1 and FIG. 2.

In the present embodiment, referring to FIG. 12 and FIG. 8, the first shielding layer 41 in the first area A1 overlaps with the first light-emitting elements 31 in the first area A1, and the second shielding layer 42 in the second area A2 overlaps with the circuit elements 20 in the second area A2 but does not overlap with the second light-emitting elements 32 in the second area A2.

In an embodiment of the present disclosure, the second shielding layer 42 is also provided in the second area A2 on the periphery of the first area A1. As a result, the cathode layer CE0 in the second area A2 can be protected during the process of etching the cathode layer CE0 in the first area A1 by the laser, thereby preventing the cathodes CE in the second light-emitting elements 32 in the second area A2 from being etched off.

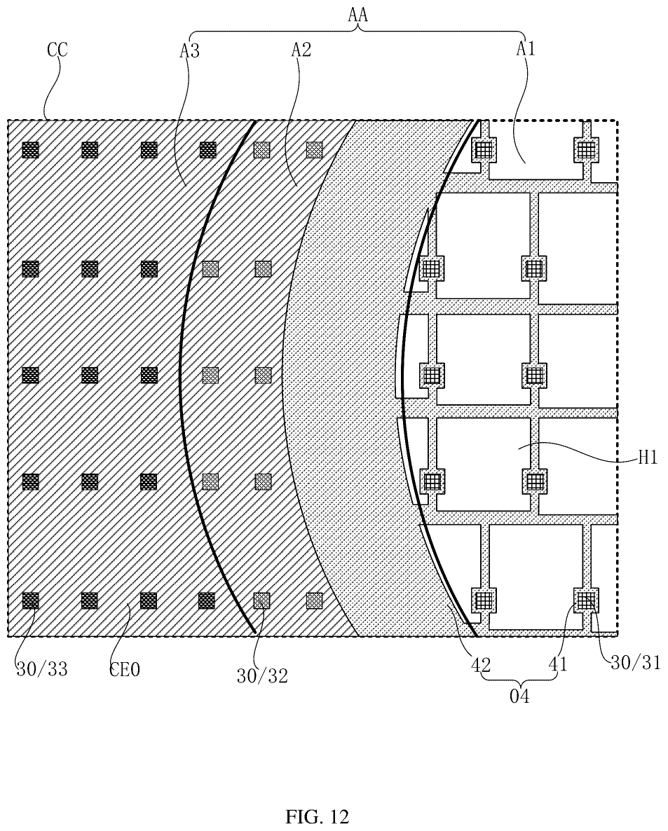

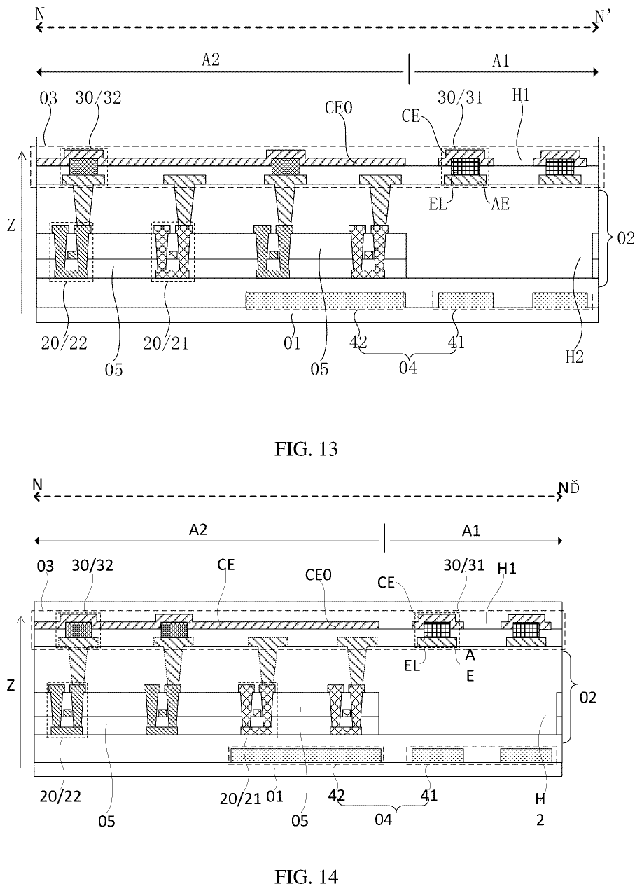

FIG. 13 is another schematic cross-sectional view along the direction MM′ in FIG. 3. FIG. 14 is another schematic cross-sectional view along the direction NN′ in FIG. 6.

In an embodiment of the present disclosure, as shown in FIG. 13 and FIG. 14, the display panel 001 further includes a plurality of insulating layers 05. The insulating layers 05 are provided at a side of the shielding layers 04 away from the substrate 01. Some of the insulating layers 05 may be provided between adjacent conductive film layers.

In an embodiment of the present disclosure, the insulating layer 05 may include a second hollow portion H2, and the second hollow portion H2 included in the insulating layer 05 is specifically arranged in the first area A1. For example, as shown in FIG. 13 and FIG. 14, the insulating layer between adjacent conductive structures in the circuit element 20 includes a second hollow portion H2 in the first area A1. That is, at least part of the insulating layer 05 extends in the second area A2 and the third area A3, and is hollow in the first area A1. By reducing the number of the insulating layers 05 in the first area A1, the optical loss of light passing through the plurality of film layers with different refractive indexes can be reduced.

In addition, in the present embodiment, the insulating layer 05 including the second hollow portion H2 may be regarded as an entire continuous structure in addition to the via hole which is provided for avoiding electrical connection of different layers in the second area A2 and the third area A3.

In an embodiment, as shown in FIG. 13 and FIG. 14, the cathode layer CE0 in the first area A1 includes a first hollow portion H1, and part of the insulating layer 05 in the first area A1 includes a second hollow portion H2. The first hollow portion H1 and the second hollow portion H2 may at least partially overlap with each other. That is, the first area A1 includes both the first hollow portion H1 and the second hollow portion H2.

In an embodiment, along the direction Z perpendicular to the display panel 001, the second hollow portion H2 may cover the first hollow portion H1. Moreover, the insulating layer 05 including the second hollow portion H2 may be completely hollow in the first area A1.

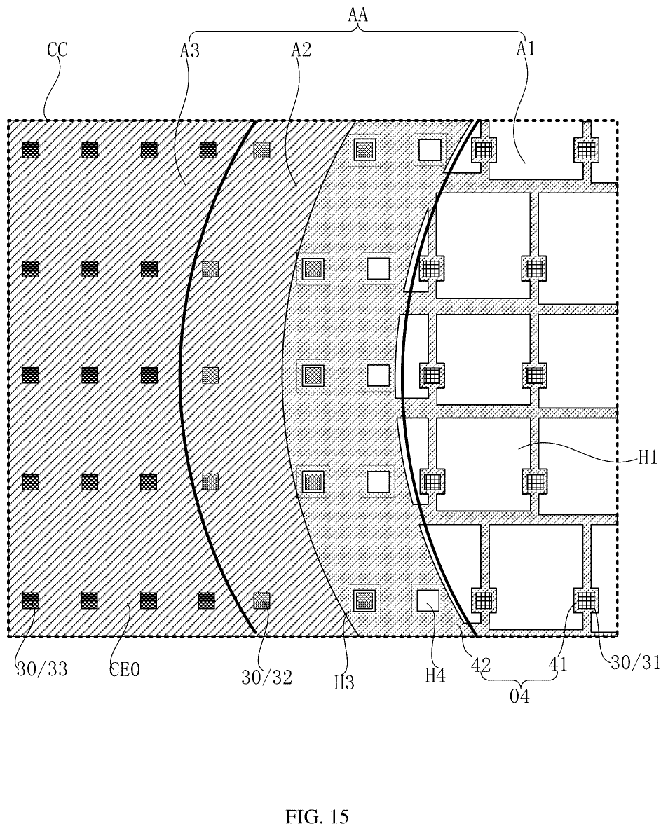

FIG. 15 is another partial schematic diagram of a CC area in a dashed box in FIG. 1 and FIG. 2.

As shown in FIG. 15, when the cathode layer CE0 includes the first hollow portion H1, the cathode layer CE0 may further include a third hollow portion H3, and the third hollow portion H3 included in the cathode layer CE0 is provided in the second area A2. In addition, the total area of the first hollow portions H1 included per unit area is greater than the total area of the third hollow portions H3 included per unit area.

For example, as shown in FIG. 15, an area of a single first hollow portion H1 is greater than an area of a single third hollow portion H3.

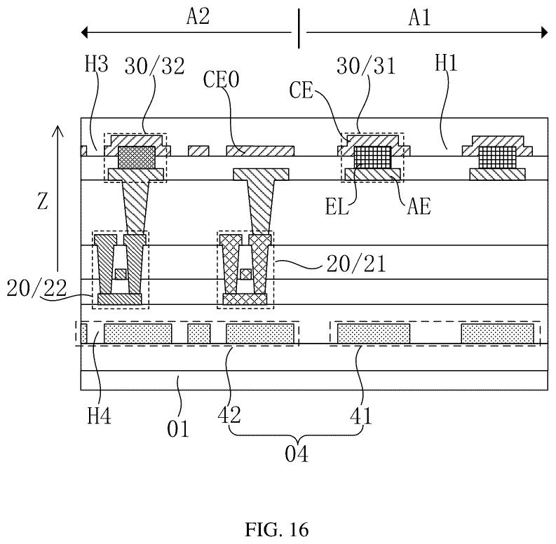

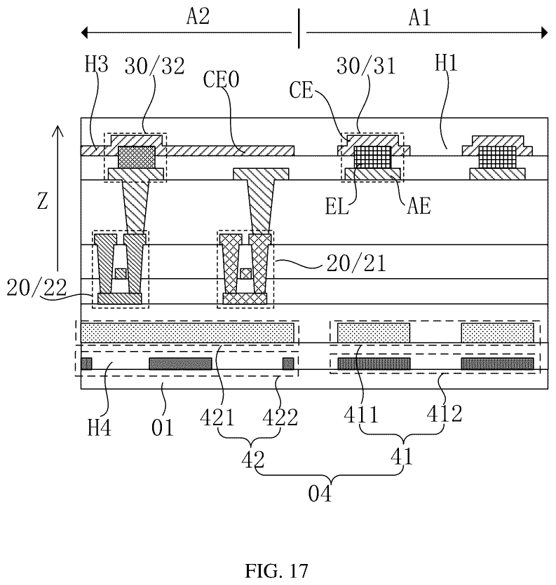

FIG. 16 is another schematic cross-sectional view along the direction MM′ in FIG. 3. FIG. 17 is another schematic cross-sectional view along the direction MM′ in FIG. 3.

In an embodiment of the present disclosure, as shown in FIG. 16 and FIG. 17, the second shielding layer 42 includes a fourth hollow portion H4. The fourth hollow portion H4 exposes at least a part of the circuit elements 20 in the second area A2. That is, the fourth hollow portion H4 exposes at least a part of the second circuit elements 22.

The fourth hollow portion H4 exposing at least a part of the second circuit elements 22 is provided in the second shielding layer 42, such that the coupling effect of the fourth hollow portion H4 on the second circuit elements 22 can be reduced, thereby ensuring the performance of the second circuit elements 22.

In an embodiment, as shown in FIG. 16, regardless of whether the second shielding layer 42 includes one sub-shielding layer or a plurality of sub-shielding layers, the fourth hollow portion H4 penetrates all the sub-shielding layers in the second shielding layer 42.

In an embodiment, as shown in FIG. 16, the third hollow portion H3 and the fourth hollow portion H4 may at least partially overlap with each other.

In an embodiment, as shown in FIG. 17, when the second shielding layer 42 includes a plurality of shielding sub-layers, the fourth hollow portion H4 penetrates through a part of the shielding sub-layers.

For example, as shown in FIG. 17, the second shielding layer 42 includes a sub-shielding layer 421 and a sub-shielding layer 422. The sub-shielding layer 421 is made of a metal material and used for reflecting laser. The sub-shielding layer 422 is made of a material with relatively high absorbance. The fourth hollow portion H4 may penetrate through the sub-shielding layer 422, but does not penetrate through the sub-shielding layer 421. As a result, the second shielding layer 42 may protect the film layer in the second area A2 from the laser to a greater extent, and reduce the coupling effect of the second shielding layer 42 on the second circuit elements 22 in the second area A2.

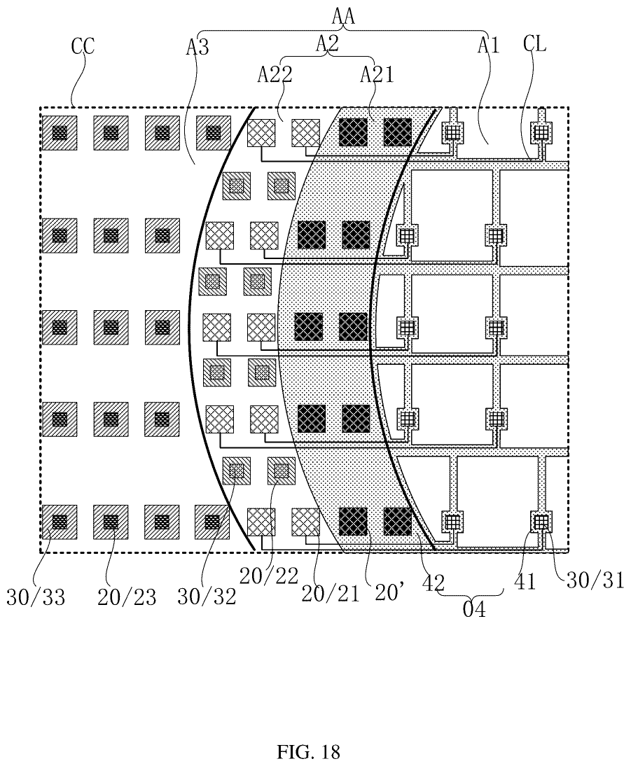

FIG. 18 is another partial schematic diagram of a CC area in a dashed box in FIG. 1 and FIG. 2.

In an embodiment of the present disclosure, as shown in FIGS. 3, 6 and 18, the second area A2 includes a first sub-area A21 and a second sub-area A22. The first sub-area A21 is located at a side of the second sub-area A22 close to the first area A1, and the second shielding layer 42 is provided in the first sub-area A21. In the present embodiment, the first sub-area A21 and the second sub-area A22 are different areas in the second area A2. The first sub-area A21 is arranged adjacent to the first area A1. In addition, the second sub-area A22 does not provided with the shielding layer 04, and the first sub-area A21 is provided with the second shielding layer 42.

Since the second shielding layer 42 affects the circuit elements 20 in the second area A2, lead to performance difference between the circuit elements 20 overlapping with the second shielding layer 42 and other circuit elements 20. In order to reduce the performance difference between the circuit elements 20 overlapping with the second shielding layer 42 and other circuit elements 20, the arrangement of the circuit elements 20 in the first sub-area A21 and the second sub-area A22 may be different to reduce the influence of the second shielding layer 42 in the second area A2 on the circuit elements 20 in the second area A2.

In the present embodiment, the circuit elements 20 in the first sub-area A21 and the second sub-area A22 may be designed differently, and therefore, the second shielding layer 42 only arranged in the first sub-area A21 may be of an entire continuous structure. Correspondingly, the cathode layer CE0 in the first sub-area A21 may also be of an entire continuous structure. The cathode layer CE0 in the first area A1 may still include a first hollow portion H1.

In an embodiment, as shown in FIG. 18, the circuit elements 20 arranged in the second area A2 are located in the second sub-area A22. That is, the first circuit elements 21 and the second circuit elements 22 located in the second area A2 are specifically arranged in the second sub-area A22, rather than in the first sub-area A21. Therefore, in the present embodiment, neither the first circuit elements 21 nor the second circuit elements 22 in the second area A2 overlap with the second shielding layer 42. In this case, when at least part of the second shielding layer 42 is made of a metal material, the second shielding layer 42 does not generate a coupling capacitance with the first circuit elements 21 and the second circuit elements 22, so that the second shielding layer 42 has an extremely small effect on the first circuit elements 21 and the second circuit elements 22.

In an embodiment, the display panel 001 further includes dummy circuit elements 20′. The dummy circuit elements 20′ may also be provided in the array layer 02, and the dummy circuit element 20′ may have the same circuit structure as at least one of the first circuit element 21 and the second circuit element 22.

In the present embodiment, the dummy circuit elements 20′ is provided in the first sub-area A21 and electrically insulated from the light emitting elements 30. That is, the dummy circuit element 20′ is not configured to provide voltage or current to the light-emitting element 30, and the output terminal of the dummy circuit element 20′ may be in a floating state. Furthermore, the dummy circuit element 20′ may remain inactive all the time.

In this implementation manner, the dummy circuit elements 20′ are arranged in the first sub-area A21 and overlaps with the second shielding layer 42 in the first sub-area A21. In an embodiment, the second shielding layer 42 may cover the dummy circuit elements 20′. In this implementation manner, the circuit elements 20 may be arranged to avoid the second shielding layer 42 to protect the working performance of the circuit elements 20 from being affected by the second shielding layer 42. Meanwhile, the dummy circuit elements 20′ are arranged below the second shielding layer 42. As a result, the thickness of the array layer 02 may be relatively uniform in the second area A2, the yield of signal lines and the like can be ensured, and at the same time, the display effect difference caused by the thickness difference is avoided.

In an embodiment, as shown in FIG. 3 and FIG. 6, circuit elements 20 are provided in both the first sub-area A21 and the second sub-area A22. That is, at least a part of the first circuit elements 21 and/or at least a part of the second circuit elements 22 overlap with the second shielding layer 42. In some embodiments, the circuit element 20 may include elements constituting a pixel circuit, such as a thin film transistor (TFT), a wiring, and a capacitor. In an embodiment, the circuit element 20 is a thin film transistor. The thin film transistor is connected to the light-emitting element 30 such as a light-emitting diode (LED), so as to cause the driving current to flow to the light-emitting element 30, so that the light-emitting element 30 can emit light according to the driving current.

Because the second shielding layer 42 affects the circuit elements 20 in the second area A2, the performance of the circuit elements 20 overlapping with the second shielding layer 42 is different from the performance of other circuit elements 20. In order to reduce the performance difference between the circuit elements 20 overlapping with the second shielding layer 42 in the second area A2 and other circuit elements 20, the channel width-to-length ratios of the circuit elements 20 in the first sub-area A21 and the second sub-area A22 may be configured to be different from each other.

In an embodiment, the channel width-to-length ratio of the circuit element 20 in the first sub-area A21 may be greater than the channel width-to-length ratio of the circuit element 20 in the second sub-area A22. A relatively large channel width-to-length ratio of the circuit element 20 in the first sub-area A21 can reduce the degree of the external interference on the circuit element 20 overlapping with the second shielding layer 42, and the coupling effect of the circuit element 20 overlapping with the second shielding layer 42 by the second shielding layer 42 would be no longer obvious.

The channel width-to-length ratio of the first circuit element 21 provided in the second area A2 will be described below as an example. It should be noted that the channel width-to-length ratio of the second circuit element 22 provided in the second area A2 may also adopt the following inventive concept.

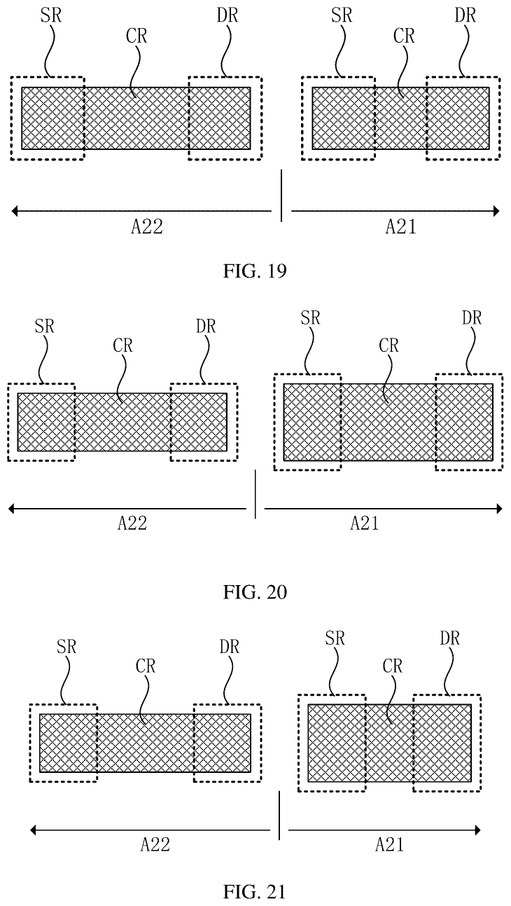

FIG. 19 is a schematic diagram of a channel width-to-length ratio of the circuit element in different sub-areas in the second area.

In an embodiment, referring to FIG. 17 and FIG. 19, the semiconductor layer in the circuit element 20 includes a source area SR, a drain area DR and a channel area CR. The channel area CR is provided between the source area SR and the drain area DR. The length of the channel area CR of the circuit element 20 in the first sub-area A21 is smaller than the length of the channel area CR of the circuit element 20 in the second sub-area A22.

FIG. 20 is a schematic diagram of a channel width-to-length ratio of the circuit elements in different sub-areas in the second area.

In an embodiment, referring to FIG. 17 and FIG. 20, the semiconductor layer in the circuit element 20 includes a source area SR, a drain area DR and a channel area CR. The channel area CR is provided between the source area SR and the drain area DR. The width of the channel area CR of the circuit element 20 in the first sub-area A21 is greater than the width of the channel area CR of the circuit element 20 in the second sub-area A22.

FIG. 21 is a schematic diagram of a channel width-to-length ratio of the circuit elements in different sub-areas in the second area.

In an embodiment, referring to FIG. 17 and FIG. 21, the semiconductor layer in the circuit element 20 includes a source area SR, a drain area DR and a channel area CR. The channel area CR is provided between the source area SR and the drain area DR. The length of the channel area CR of the circuit element 20 in the first sub-area A21 is smaller than the length of the channel area CR of the circuit element 20 in the second sub-area A22. The width of the channel area CR of the circuit element 20 in the first sub-area A21 is greater than the width of the channel area CR of the circuit element 20 in the second sub-area A22.

In the present embodiment, the length of the channel area CR of the circuit element 20 in the first sub-area A21 is smaller than the length of the channel area CR of the circuit element 20 in the second sub-area A22. Additionally or separately, the width of the channel area CR of the circuit element 20 in the first sub-area A21 is greater than the width of the channel area CR of the circuit element 20 in the second sub-area A22. That is, the width-to-length ratio of the channel area CR of the circuit element 20 in the first sub-area A21 is greater than the width-to-length ratio of the channel area CR of the circuit element 20 in the second sub-area A22. Therefore, the amplitude of the driving current flowing through the circuit element 20 in the first sub-area A21 is greater than that of the driving current flowing through the circuit element 20 in the second sub-area A22.

Specifically, in the present embodiment, the circuit element 20 is a thin film transistor connected to the light emitting element 30, so as to cause the driving current to flow to the light emitting element 30, so that the light emitting element 30 can emit light according to the driving current. Therefore, when the amplitude of the driving current flowing through the circuit element 20 in the first sub-area A21 is greater than the amplitude of the driving current flowing through the circuit element 20 in the second sub-area A22, the display brightness of the second sub-area A22 can be greater than the display brightness of the first sub-area A21, so that the display brightness can uniformly transitions from the first area A1 to the third area A3.

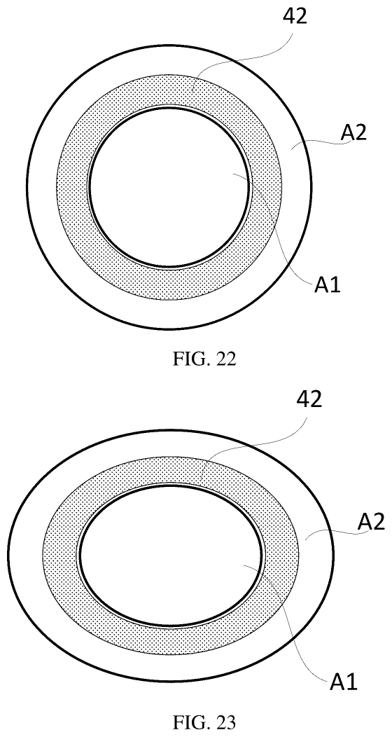

FIG. 22 is a schematic projection diagram of a second shielding layer provided by an embodiment of the present disclosure. FIG. 23 is a schematic projection diagram of a second shielding layer provided by an embodiment of the present disclosure.

In an embodiment of the present disclosure, as shown in FIG. 22 and FIG. 23, the edge of the second shielding layer 42 close to the first area A1 extends along the edge contour of the first area A1. That is, the edge of the second shielding layer 42 close to the first area A1 extends around the edge contour of the first area A1. It could be understood that the shape of the edge of the second shielding layer 42 close to the first area A1 and the shape of the edge contour of the first area A1 are similar or the same pattern. That is, the shape of the edge of the second shielding layer 42 close to the first area A1 may be defined according to the shape of the edge contour of the first area A1.

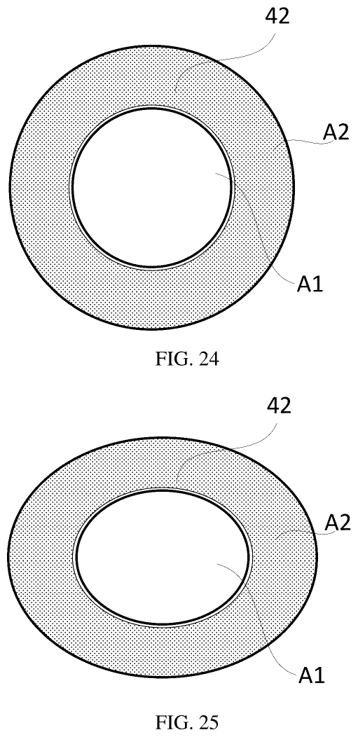

In the accompanied drawings corresponding to this embodiment, the first area A1 and the second area A2 are divided by a thicker line in the figure as the boundary, that is, the area enclosed by the thicker inner line is indicated as the first area A1, and the area between the thicker inner line and the thicker outer line is indicated as the second area A2. The division of the second shielding layer 42, the first area A1 and the second area A2 in the drawings corresponding to the following embodiments (i.e., FIGS. 24 to 33) also obeys this principle.

In addition, as shown in FIG. 22 and FIG. 23, an edge of the second shielding layer 42 close to the first area A1 may coincide with an edge contour of the first area A1, or the edge of the second shielding layer 42 close to the first area A1 is located outside the first area A1, so that the second shielding layer 42 can effectively block unnecessary etching of the film layer in the second area A2 by the laser while not affecting the light transmittance of the first area A1.

It should be noted that the edge of the second shielding layer 42 close to the first area A1 may include fine sawteeth. The shape of the edge of the second shielding layer 42 close to the first area A1 may be a relatively smooth shape neglecting sawteeth. The edge of the second shielding layer 42 close to the first area A1 includes a plurality of fine sawteeth, which can reduce diffraction of the edge of the first area A1 and the edge of the second area A2 close to the first area A1.

In an implementation manner, the edge contour of the first area A1 has a shape of one of a circle and an ellipse. Correspondingly, the edge of the second shielding layer 42 close to the first area A1 has a shape of one of a circle and an ellipse. For example, as shown in FIG. 22, both the edge contour of the first area A1 and the edge of the second shielding layer 42 close to the first area A1 are circular. Alternatively, both the edge contour of the first area A1 and the edge of the second shielding layer 42 close to the first area A1 are elliptical.

In this embodiment, the shape of the edge of the second shielding layer 42 away from the first area A1 is configured to be similar to the shape of the edge contour of the first area A1. In other words, the shape of the edge of the second shielding layer 42 away from the first area A1 may be defined according to the shape of the edge contour of the first area A1. Then, the widths of the second shielding layer 42 at all the positions may be the same. In this case, the number of the circuit elements 20 in different circuit element rows shielded by the second shielding layer 42 are substantially the same, and the number of the circuit elements 20 in different circuit element columns shielded by the second shielding layer 42 are also substantially the same, which facilitates compensation for different circuit elements 20.

FIG. 24 is a schematic projection diagram of a second shielding layer provided by an embodiment of the present disclosure. FIG. 25 is a schematic projection diagram of a second shielding layer provided by an embodiment of the present disclosure.

In an embodiment of the present disclosure, as shown in FIG. 22 and FIG. 23, along a direction perpendicular to the display panel, the projection of the second shielding layer 42 partially covers the second area A2. That is, the second shielding layer 42 is provided at some positions of the second area A2, and is not provided in some other positions of the second area A2.

In addition, in the second area A2, positions where the second shielding layer 42 is arranged are closer to the first area A1 than positions where the second shielding layer 42 is not arranged.

In an embodiment of the present disclosure, as shown in FIG. 24 and FIG. 25, the projection of the second shielding layer 42 completely covers the second area A2. That is, the second shielding layer 42 is provided at all positions in the second area A2.

In an embodiment of the present disclosure, as shown in FIGS. 22 to 25, an edge of the second shielding layer 42 away from the first area A1 has the same contour as an edge of the second area A2 away from the first area A1. It may be understood that the shape of the edge of the second shielding layer 42 away from the first area A1 and the shape of the edge contour of the second area A2 away from the first area A1 are similar or the same patterns. That is, the shape of the edge of the second shielding layer 42 away from the first area A1 may be defined according to the shape of the edge contour of the second area A2 away from the first area A1.

In the related art, when the display panel 001 includes the first area A1 and the second area A2 and the circuit elements 20 electrically connected to the light-emitting elements 30 in the first area A1 are provided in the second area A2, the circuit elements 20 in the second area A2 may be compensated. In an embodiment of the present disclosure, when the shape of the edge of the second shielding layer 42 away from the first area A1 is similar to or the same as the shape of the edge of the second area A2 away from the first area A1, it is easy to compensate the circuit elements 20 in the second area A2.

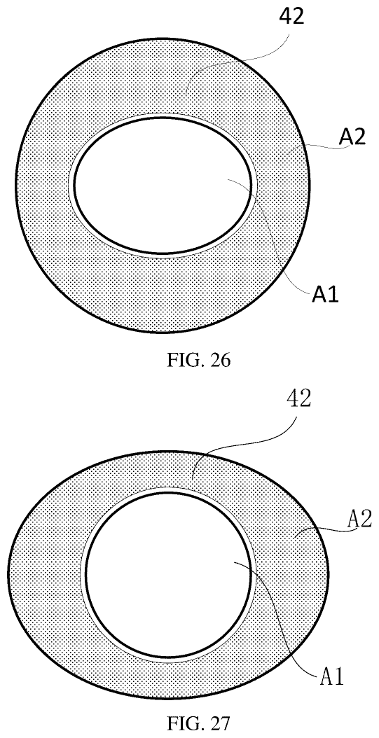

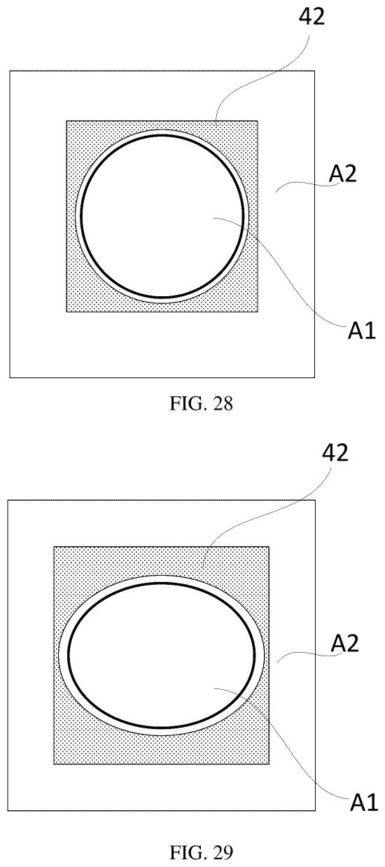

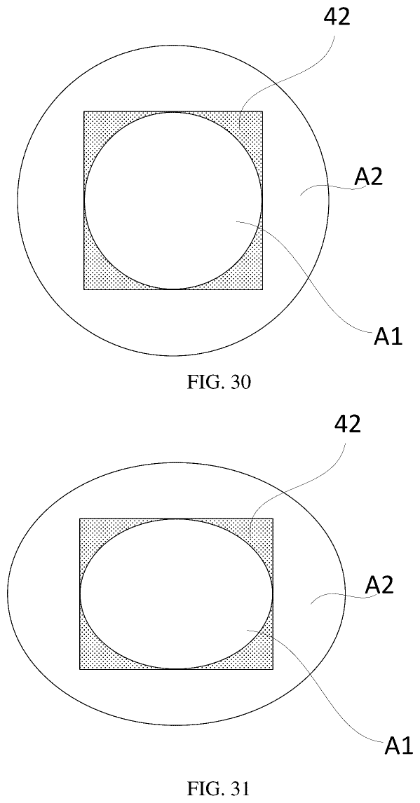

FIG. 26 is a schematic projection diagram of a second shielding layer provided by an embodiment of the present disclosure. FIG. 27 is a schematic projection diagram of a second shielding layer provided by an embodiment of the present disclosure. FIG. 28 is a schematic projection diagram of a second shielding layer provided by an embodiment of the present disclosure. FIG. 29 is a schematic projection diagram of a second shielding layer provided by an embodiment of the present disclosure.

In an embodiment, the edge of the second area A2 away from the first area A1 has a shape of one of a circle, an ellipse and a rectangle. Correspondingly, the shape of the edge of the second shielding layer 42 away from the first area A1 has a shape of one of a circle, an ellipse and a rectangle. For example, as shown in FIGS. 22, 24 and 26, the edge of the second shielding layer 42 away from the first area A1 and the edge of the second area A2 away from the first area A1 are both circular; or as shown in FIGS. 23, 25 and 27, the edge of the second shielding layer 42 away from the first area A1 and the edge of the second area A2 away from the first area A1 are both elliptical; or as shown in FIG. 28 and FIG. 29, the edge of the second shielding layer 42 away from the first area A1 and the edge of the second area A2 away from the first area A1 are both rectangular, which may be specifically square.

FIG. 30 is a schematic projection diagram of a second shielding layer provided by an embodiment of the present disclosure. FIG. 31 is a schematic projection diagram of a second shielding layer provided by an embodiment of the present disclosure.

In an embodiment of the present disclosure, as shown in FIG. 30 and FIG. 31, the edge of the second shielding layer 42 away from the first area A1 has a rectangular shape. The edge contour of the first area A1 has a shape of one of a circle and an ellipse. At least one side of the second shielding layer 42 away from the edge of the first area A1 is tangent to the edge contour of the first area A1.

The outer contour of the second shielding layer 42 is provided as a rectangular shape, so that part of the film layer in the first area A1 may be etched by using linear laser, and the outer contour of the second shielding layer 42 may surround a moving path of the linear laser, thereby effectively avoiding unnecessary etching of the film layer in the second area A2 by the laser. In addition, at least one side of the second shielding layer 42 away from the edge of the first area A1 is tangent to the edge contour of the first area A1, so that the film layer in the second area A2 will not be unnecessarily etched as long as the laser does not exceed the side. Meanwhile, the second shielding layer 42 can have a smaller width in the direction perpendicular to the side, thereby reducing the influence of the second shielding layer 42 on the circuit elements 20 in the second area A2.

In an embodiment, as shown in FIG. 30 and FIG. 31, each side of the second shielding layer 42 away from the edge of the first area A1 is tangent to the edge contour of the first area A1. In this case, in the process of etching part of the film layer in the first area A1 by using the linear laser, the second shielding layer 42 can have a minimum area while it is ensured that the laser does not unnecessarily etch the film layer in the second area A2, thereby reducing the influence of the second shielding layer 42 on the circuit elements 20 in the second area A2.

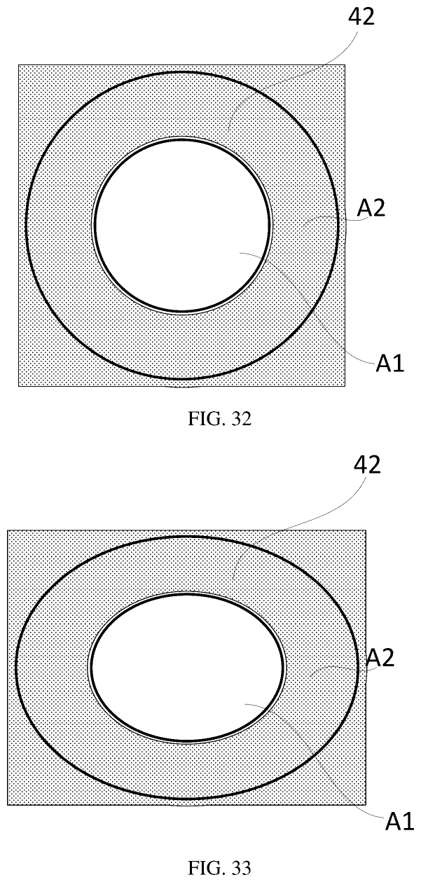

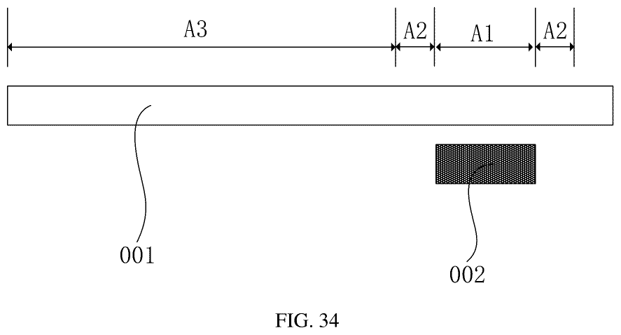

FIG. 32 is a schematic projection diagram of a second shielding layer provided by an embodiment of the present disclosure. FIG. 33 is a schematic projection diagram of a second shielding layer provided by an embodiment of the present disclosure.

In an embodiment of the present disclosure, as shown in FIG. 32 and FIG. 33, part of the second shielding layer 42 extends to the periphery of the second area A2. That is, the second shielding layer 42 includes not only the part located in the second area A2, but also the part located in the third area A3. In this case, the second shielding layer 42 can also prevent the part of the film layer in the third area A3 close to the second area A2 from being unnecessarily etched.

FIG. 34 is a schematic diagram of a display device provided by an embodiment of the present disclosure.

An embodiment of the present disclosure further provides a display device. As shown in FIG. 34, the display device provided by the embodiment of the present disclosure may include the display panel 001 according to any one of the above embodiments. The display device provided by an embodiment of the present disclosure may be a mobile phone. In addition, the display device provided by an embodiment of the present disclosure may also be such as a computer or a television.

As shown in FIG. 34, the display device provided by an embodiment of the present disclosure further includes an optical functional element 002. The optical functional element 002 is provided at a position of the display device corresponding to the first area A1 of the display panel 001. That is, along a direction perpendicular to the plane where the display panel 001 is located, the optical functional element 002 is provided below the first area A1 of the display panel 001. In this case, the optical functional element 002 may emit light to the side of the light-emitting surface of the display panel 001 through the first area A1, and/or may receive light from the side of the light-emitting surface of the display panel 001 through the first area A1.

The optical functional element 002 is at least one of an optical fingerprint sensor, an iris recognition sensor, and a camera.

In an embodiment of the present disclosure, the light transmittance of the first area A1 is greater than the light transmittance of the second area A2. At least part of the film layer in the first area A1 is etched off by laser to increase the light transmittance of the first area A1. The first shielding layer 41 overlapping with the light emitting elements 20 is provided in the first area A1, so that the film layer in the light emitting elements 20 can be protected from being etched by laser. The second shielding layer 42 is provided in the second area A2, so that the film layer in the second area A2 can be protected from being misetched.

An embodiment of the present disclosure further provides a manufacturing method of a display panel, for preparing the display panel 001 according to any one of the above embodiments.

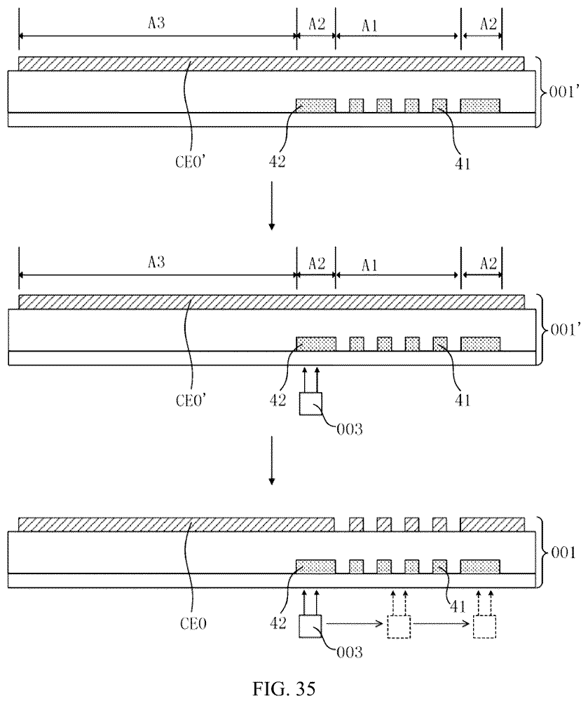

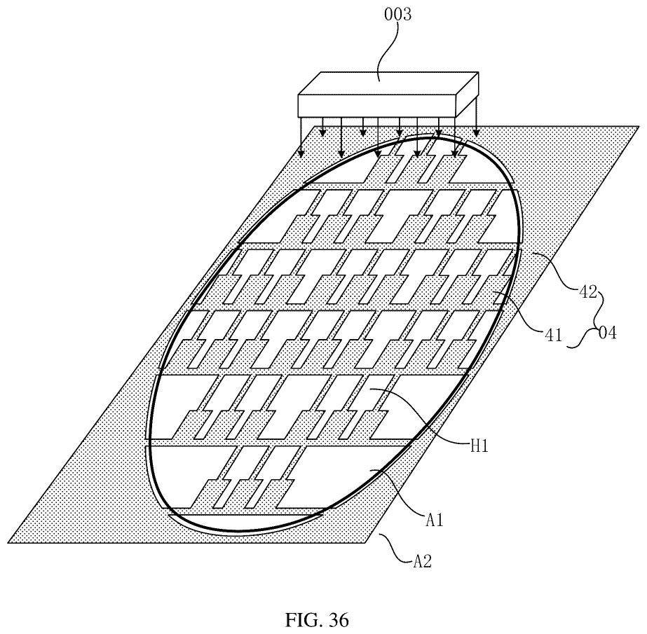

FIG. 35 is a schematic diagram of a manufacturing method of a display panel according to an embodiment of the present disclosure.

As shown in FIG. 35, the manufacturing method according to an embodiment of the present disclosure includes:

Providing an initial display panel 001′. The initial display panel 001′ includes an initial cathode layer CE0′ and the initial cathode layer CE0′ is an entire continuous structure. The patterned first shielding layer 41 in the first area A1 partially overlaps with the initial cathode layer CE0′. In an embodiment, the first shielding layer 41 in the first area A1 surrounds a plurality of first hollow portions H1, and the first hollow portions H1 overlap with the part of the initial cathode layer CE0′ that needs to be etched by laser.

The initial cathode layer CE0′ in the first area A1 is etched by using the linear laser 003, the part of the initial cathode layer CE0′ that overlaps with the first shielding layer 41 remains and the part of the initial cathode layer CE0′ that does not overlap with the first shielding layer 41 is etched off. In the process of etching the initial cathode layer CE0′ by using the linear laser 003, the first shielding layer 41 may reflect the laser so that the laser does not reach the part of the initial cathode layer CE0′ that overlaps the first shielding layer 41, and the laser may reach the initial cathode layer CE0 by passing through the first hollow portion H1 to′, so that the part of the initial cathode layer CE0′ that overlaps with the first hollow portion H1 will be etched off by the laser.

In a direction Z perpendicular to the display panel, an edge of the second shielding layer 42 in the second area A2 away from the first area A1 surrounds a path of etching the initial cathode layer CE0′ in the first area A1 by the linear laser. For example, as shown in FIG. 33, when the linear laser 003 moves along the left-right direction in FIG. 33, a path of the linear laser 003 moving along the left-right direction does not exceed an edge of the second shielding layer 42 in the left-right direction.

In an embodiment of the present disclosure, the linear laser 003 mainly etches the initial cathode layer CE0′ in the first area A1. Since the first area A1 is generally circular or elliptical, in the process of etching the initial cathode layer CE0′ in the first area A1, the path of the linear laser 001 is generally rectangular. That is, the path of the linear laser 001 would definitely exceed the range of the first area A1. In an embodiment of the present disclosure, the outer path of the second shielding layer 42 in the second area A2 is configured to be greater than the moving path of the linear laser 001, which can avoid unnecessary etching of the film layer in the second area A2 by the linear laser 001.

FIG. 36 is a schematic diagram of a relationship between a linear laser and a second shielding layer in a display panel provided by an embodiment of the present disclosure.

In an embodiment of the present disclosure, as shown in FIG. 36, a shape of an edge of the second shielding layer 42 in the second area A2 away from the first area A1 is a rectangle, and a path of the linear laser 003 when etching the initial cathode layer CE0′ in the first area A1 coincides with a area where the rectangle is located. The shape and size of the second shielding layer 42 are consistent with the shape and size formed by the moving path of the linear laser 003, which can ensure that the second shielding layer 42 protects the film layer in the second area A2 from unnecessary etching, and further make the second shielding layer 42 have a relatively small area.

It should be noted that the path of the linear laser 003 when etching the initial cathode layer CE0′ in the first area A1 coincides with the area where the rectangle is located, which refers to that the path of etching the initial cathode layer CE0′ in the first area A1 by the linear laser 003 substantially coincides with the area where the rectangle is located within the process precision range.

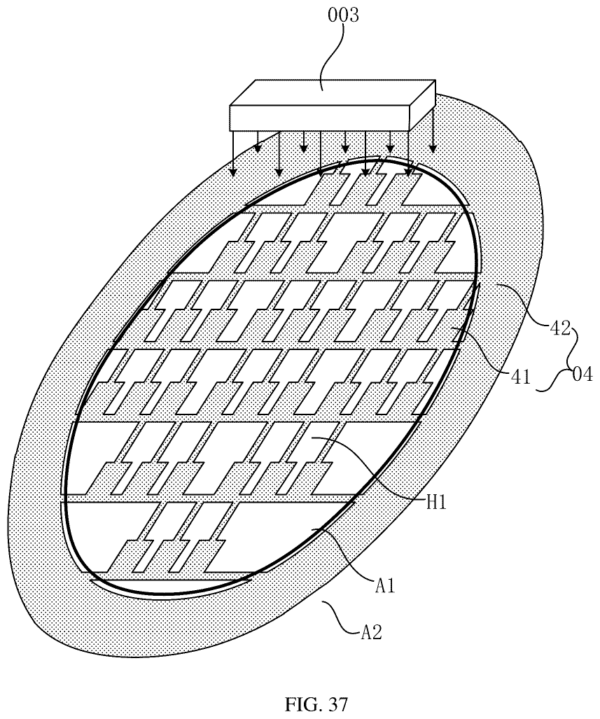

FIG. 37 is a schematic diagram of a relationship between a linear laser and a second shielding layer in a display panel provided by an embodiment of the present disclosure.

In an embodiment of the present disclosure, as shown in FIG. 37, an edge of the second shielding layer 42 in the second area A2 away from the first area A1 has a shape of one of a circle and an ellipse. Along a direction perpendicular to the display panel 001, the circle or the ellipse surrounds the path of the linear laser 003 etching the initial cathode layer CE0′ in the first area A1.

The above descriptions are merely preferred embodiments of the present disclosure and are not intended to limit the present disclosure. It should be noted that any modifications, equivalent substitutions, improvements, and the like made within the spirit and principle of the present disclosure shall fall within the protection scope of the present disclosure.

1. A display panel, wherein a display area of the display panel comprises a first area and a second area, the first area and the second area are adjacent to each other, and light transmittance of the second area is less than light transmittance of the first area; and
the display panel comprises:
a substrate;
an array layer provided at a side of the substrate, and comprising a plurality of circuit elements;
a plurality of light-emitting elements provided at a side of the array layer away from the substrate; and
shielding layers provided at a side of the plurality of light-emitting elements facing the substrate, and comprising a first shielding layer and a second shielding layer;
wherein the first shielding layer overlaps with light-emitting elements in the first area, and
the second shielding layer overlaps with circuit elements and/or or light-emitting elements in the second area.

2. The display panel according to claim 1, wherein a cathode layer of the plurality of light-emitting elements comprises a first hollow portion provided in the first area; or
the display panel further comprises:
an insulating layer provided at a side of the shielding layers that is away from the substrate, and comprising a second hollow portion provided in the first area.

3. The display panel according to claim 2, wherein the cathode layer further comprises a third hollow portion provided in the second area; and
wherein a total area of the first hollow portion comprised per unit area is greater than a total area of the third hollow portion comprised per unit area.

4. The display panel according to claim 1, wherein the plurality of circuit elements comprises a first circuit element, and the plurality of light-emitting elements comprises a first light-emitting element; and
the first light-emitting element is provided in the first area, the first circuit element is provided in the second area, and the first circuit element is electrically connected to the first light-emitting element.

5. The display panel according to claim 4, wherein the plurality of circuit elements comprises a second circuit element, and the plurality of light-emitting elements comprises a second light-emitting element; and
the second circuit element and the second light-emitting element are both provided in the second area, and the second circuit element is electrically connected to the second light-emitting element.

6. The display panel according to claim 5, wherein the plurality of circuit elements comprises a third circuit element, and the plurality of light-emitting elements comprises a third light-emitting element; and
the display area further comprises a third area, the second area is located between the first area and the third area, the third circuit element and the third light-emitting element are both provided in the third area, and the third circuit element is electrically connected to the third light-emitting element.

7. The display panel according to claim 1, wherein the second shielding layer comprises a fourth hollow portion, and the fourth hollow portion exposes at least a part of circuit elements in the second area.

8. The display panel according to claim 1, wherein the second area comprises a first sub-area and a second sub-area, and the first sub-area is located at a side of the second sub-area close to the first area; and
wherein circuit elements in the second area are located in the second sub-area, and the second shielding layer is provided in the first sub-area.

9. The display panel according to claim 8, wherein the display panel further comprises a dummy circuit element provided in the first sub-area and electrically insulated from the light-emitting elements.

10. The display panel according to claim 1, wherein the second area comprises a first sub-area and a second sub-area, the first sub-area is located at a side of the second sub-area close to the first area, the second shielding layer is provided in the first sub-area, and both the first sub-area and the second sub-area are provided with circuit elements; and
the circuit element comprises a channel area, and a length of the channel area of the circuit element provided in the first sub-area is less than a length of the channel area of the circuit element provided in the second sub-area.

11. The display panel according to claim 1, wherein the second area comprises a first sub-area and a second sub-area, and the first sub-area is located at a side of the second sub-area close to the first area, the second shielding layer is provided in the first sub-area, and both the first sub-area and the second sub-area are provided with circuit elements; and
the circuit element comprises a channel area, and a width of the channel area of the circuit element provided in the first sub-area is greater than a width of the channel area of the circuit element provided in the second sub-area.

12. The display panel according to claim 1, wherein an edge of the second shielding layer close to the first area extends along an edge contour of the first area.

13. The display panel according to claim 1, wherein an edge contour of the first area is one of a circle and an ellipse.

14. The display panel according to claim 1, wherein along a direction perpendicular to the display panel, a projection of the second shielding layer partially covers the second area, or a projection of the second shielding layer completely covers the second area.

15. The display panel according to claim 1, wherein an edge of the second shielding layer away from the first area has a same contour as an edge of the second area away from the first area.

16. The display panel according to claim 1, wherein an edge of the second area away from the first area has a shape of one of a circle, an ellipse and a rectangle.

17. The display panel according to claim 1, wherein an edge of the second shielding layer away from the first area has a shape of a rectangle, and an edge contour of the first area has a shape of one of a circle and an ellipse; and
at least one side of the edge of the second shielding layer away from the first area is tangent to the edge contour of the first area.

18. The display panel according to claim 17, wherein each side of the edge of the second shielding layer away from the first area is tangent to the edge contour of the first area.

19. The display panel according to claim 1, wherein a part of the second shielding layer extends to a periphery of the second area.

20. The display panel according to claim 1, wherein the first shielding layer comprises n sub-shielding layers stacked with one another, and the second shielding layer comprises m sub-shielding layers stacked with one another, wherein n>m.

21. The display panel according to claim 20, wherein at least one sub-shielding layer in the first shielding layer and at least one sub-shielding layer in the second shielding layer are provided in a same layer and made of a same material.

22. A display device comprising a display panel, wherein a display area of the display panel comprises a first area and a second area, the first area and the second area are adjacent to each other, and light transmittance of the second area is less than light transmittance of the first area; and
the display panel comprises:
a substrate;
an array layer provided at a side of the substrate, and comprising a plurality of circuit elements;
a plurality of light-emitting elements provided at a side of the array layer away from the substrate; and
shielding layers provided at a side of the plurality of light-emitting elements facing the substrate, and comprising a first shielding layer and a second shielding layer;
wherein the first shielding layer overlaps with light-emitting elements in the first area, and
the second shielding layer overlaps with circuit elements or light-emitting elements in the second area.

23. A manufacturing method of a display panel, wherein a display area of the display panel comprises a first area and a second area, the first area and the second area are adjacent to each other, and light transmittance of the second area is less than light transmittance of the first area; and
the display panel comprises:
a substrate;
an array layer provided at a side of the substrate, and comprising a plurality of circuit elements;
a plurality of light-emitting elements provided at a side of the array layer away from the substrate; and
shielding layers provided at a side of the plurality of light-emitting elements facing the substrate, and comprising a first shielding layer and a second shielding layer;
wherein the first shielding layer overlaps with light-emitting elements in the first area, and
the second shielding layer overlaps with circuit elements or light-emitting elements in the second area.

24. The manufacturing method according to claim 23, comprising:
providing an initial display panel comprising an initial cathode layer, wherein the patterned first shielding layer in the first area partially overlaps with the initial cathode layer; and
etching the initial cathode layer in the first area by using a linear laser, wherein a part of the initial cathode layer overlapping with the first shielding layer remains and a part of the initial cathode layer not overlapping with the first shielding layer is etched off;
wherein an edge shape of the second shielding layer surrounds a path of etching the initial cathode layer in the first area by the linear laser along a direction perpendicular to the display panel.

25. The manufacturing method according to claim 24, wherein the edge shape of the second shielding layer in the second area is a rectangle, and the path of etching the initial cathode layer in the first area by the linear laser coincides with an area where the rectangle is located.

26. The manufacturing method according to claim 24, wherein the edge shape of the second shielding layer in the second area is one of a circle or an ellipse, and along the direction perpendicular to the display panel, the circle or the ellipse surrounds the path of etching the initial cathode layer in the first area by the linear laser.
